(19) United States
(12) Patent Application Publication
(10) Pub. No.: US 2026/0112434 A1
(43) Pub. Date: Apr. 23, 2026

(54) ONE-TIME-PROGRAMMABLE MEMORY DEVICES AND ONE-TIME-PROGRAMMABLE MEMORY CELLS HAVING ASYMMETRIC METAL GATES

(71) Applicant: Samsung Electronics Co. Ltd., Suwon-si (KR)

(72) Inventors: Seokhyeon YOON, Suwon-si (KR); Gibum Kim, Suwon-si (KR); Mirine Leem, Suwon-si (KR)

(73) Assignee: Samsung Electronics Co. Ltd., Suwon-si (KR)

(21) Appl. No.: 19/332,387

(22) Filed: Sep. 18, 2025

(30) Foreign Application Priority Data
Oct. 21, 2024 (KR) 10-2024-0144322

(51) Int. Cl. G11C 17/18; G11C 17/16; H10B 20/25

(52) U.S. Cl. CPC G11C 17/18; G11C 17/16; H10B 20/25

(57) ABSTRACT

Example embodiments are directed to a one-time-programmable (OTP) memory cell having asymmetric metal gates and an OTP memory device. The OTP memory device includes a program transistor, which has a first threshold voltage and a first breakdown voltage, and a read transistor, which is connected to the program transistor and has a second threshold voltage and a second breakdown voltage. A first gate electrode of the program transistor includes a first gate insulating layer surrounding the first gate electrode, a second gate electrode of the read transistor includes a second gate insulating layer surrounding the second gate electrode, and the thickness of the first gate electrode of the program transistor is greater than the thickness of the second gate electrode of the read transistor.

### CROSS-REFERENCE TO RELATED APPLICATION

This U.S. non-provisional application claims priority under 35 U.S.C. 119 to Korean Patent Application No. 10-2024-0144322, filed on October 21, 2024, in the Korean Intellectual Property Office, the disclosure of which is incorporated by reference herein in its entirety.

### BACKGROUND

Example embodiments of the inventive concepts relate to semiconductor memory devices including one-time-programmable (OTP) memory devices that include asymmetric metal gates to improve signal setup speed and reduce power consumption.

An OTP memory having an anti-fuse structure is a type of embedded non-volatile memory that is used in integrated circuits. The OTP memory is a reliable memory device, compatible with complementary metal oxide semiconductor (CMOS) processes, and relatively easy to program, and thus may be used in a variety of application such as in analog circuit trimming, secure code and chip identification (ID) storage, static random-access memory (SRAM)/dynamic random-access memory (DRAM) redundancy design, and/or radio frequency identification (RFID) applications. In addition, an OTP memory device may be used in a system-on-chip (SOC) and/or an internet of things (IoT) chip. Accordingly, it is advantageous to have a relatively higher performance OTP memory and have relatively higher signal speed and lower power consumption.

### SUMMARY

Example embodiments are directed to a one-time-programmable (OTP) memory device in which a program transistor and a read transistor in an OTP memory cell have different threshold voltages to improve a signal setup speed of OTP memory and reduce power consumption.

According to some example embodiments of the inventive concepts, an OTP memory device includes a plurality of OTP memory cells, wherein each of the plurality of OTP memory cells includes a program transistor having a first threshold voltage and a first breakdown voltage and a read transistor connected to the program transistor and having a second threshold voltage and a second breakdown voltage, and wherein each of the program transistor and the read transistor includes a fin-type active region extending in a first direction on a substrate, a plurality of semiconductor patterns defining a channel region and spaced apart from an upper surface of the fin-type active region, and gate electrodes extending in a second direction intersecting the first direction above the fin-type active region and arranged respectively between the plurality of semiconductor patterns, and wherein a first gate electrode of the program transistor includes a first gate insulating layer surrounding the first gate electrode, a second gate electrode of the read transistor includes a second gate insulating layer surrounding the second gate electrode, and a thickness of the first gate electrode is greater than a thickness of the second gate electrode.

According to some example embodiments of the inventive concepts, an OTP memory device includes a plurality of OTP memory cells, wherein each of the plurality of OTP memory cells includes a program transistor having a first threshold voltage and a first breakdown voltage and a read transistor connected to the program transistor and having a second threshold voltage and a second breakdown voltage, and wherein each of the program transistor and the read transistor includes a fin-type active region extending in a first direction on a substrate, a plurality of semiconductor patterns defining a channel region and spaced apart from an upper surface of the fin-type active region, and gate electrodes extending in a second direction intersecting the first direction above the fin-type active region and arranged respectively between the plurality of semiconductor patterns, and wherein a first gate electrode of the program transistor includes a first gate insulating layer surrounding the first gate electrode, a second gate electrode of the read transistor includes a second gate insulating layer surrounding the second gate electrode, the first gate electrode and the second gate electrode each include lanthanum (La), and a first concentration of the lanthanum (La) in the first gate electrode is less than a second concentration of the lanthanum (La) in the second gate electrode.

According to some example embodiments of the inventive concepts, an OTP memory device includes a plurality of OTP memory cells, wherein each of the plurality of OTP memory cells includes a program transistor having a first threshold voltage and a first breakdown voltage and a read transistor connected to the program transistor and having a second threshold voltage and a second breakdown voltage, and wherein each of the program transistor and the read transistor includes a fin-type active region extending in a first direction on a substrate, a plurality of semiconductor patterns defining a channel region and spaced apart from an upper surface of the fin-type active region, and gate electrodes extending in a second direction intersecting the first direction above the fin-type active region and arranged respectively between the plurality of semiconductor patterns, and wherein a first gate electrode of the program transistor includes a first gate insulating layer surrounding the first gate electrode, a second gate electrode of the read transistor includes a second gate insulating layer surrounding the second gate electrode, the first gate electrode and the second gate electrode each include aluminum (Al), and a first concentration of the aluminum (Al) in the first gate electrode is greater than a second concentration of the aluminum (Al) in the second gate electrode.

According to some example embodiments of the inventive concepts, a method of operating a one-time-programmable (OTP) memory device includes applying a program voltage of one or more OTP memory cells of a plurality of OTP memory cells of the OTP memory device to program the one or more OTP memory cells and applying a read voltage to read the programmed one or more OTP memory cells, the read voltage being less than the program voltage. Each OTP memory cell includes a program transistor having a first threshold voltage and a first breakdown voltage, and a read transistor connected to the program transistor and having a second threshold voltage and a second breakdown voltage, and wherein a first gate electrode of the program transistor comprises a first gate insulating layer surrounding the first gate electrode, a second gate electrode of the read transistor comprises a second gate insulating layer surrounding the second gate electrode, and a thickness of the first gate electrode is greater than a thickness of the second gate electrode. Programming the one or more OTP memory cells includes causing a breakdown of the first gate insulating layer by applying the program voltage.

According to some example embodiments of the inventive concepts, each OTP memory cell of the plurality of OTP memory cells is connected to a bit line and a word line, and wherein applying the program voltage includes applying the program voltage to the word line of the OTP memory cell in a program mode, and applying the read voltage includes applying the read voltage to the word line of the OTP memory cell in a read mode.

According to some example embodiments of the inventive concepts, the first breakdown voltage is less than the second breakdown voltage.

According to some example embodiments of the inventive concepts, the first threshold voltage is greater than the second threshold voltage.

### BRIEF DESCRIPTION OF THE DRAWINGS

Example embodiments will be more clearly understood from the following detailed description taken in conjunction with the accompanying drawings in which:

FIG. 1 is a diagram conceptually illustrating a system according to some example embodiments.

FIG. 2 is a block diagram showing a one-time-programmable (OTP) memory device according to some example embodiments.

FIG. 3 is a circuit diagram showing an example of an OTP memory cell in a memory cell array of FIG. 2.

FIG. 4 is a diagram showing a relationship between operating voltages of the OTP memory cell of FIG. 3.

FIG. 5 is a circuit diagram showing an example of the memory cell array of FIG. 2.

FIG. 6 is a schematic layout view showing an OTP memory cell array according to some example embodiments.

FIG. 7 is a cross-sectional view of the OTP memory cell array taken along line A1-A1' of FIG. 6.

FIGS. 8 and 9 are diagrams illustrating gate structures of OTP memory cells according to some example embodiments.

FIG. 10 is a block diagram of a system and illustrates an electronic product including an OTP memory device according to some example embodiments.

### DETAILED DESCRIPTION OF THE EMBODIMENTS

In the drawings, parts having no relationship with the description are omitted for clarity, and the same or similar constituent elements are indicated by the same reference numeral throughout the specification.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

Hereinafter, the terms “lower portion” and “upper portion” are for convenience of description and do not limit the positional relationship.

A one-time-programmable (OTP) memory cell according to example embodiments of the inventive concepts includes a program transistor and a read transistor. The OTP memory cell has the advantage that this cell may be formed together with surrounding transistors using a complementary metal-oxide semiconductor (CMOS) process. The CMOS process may include a FinFET process of forming a transistor having a three-dimensional structure by using an active fin. The OTP memory cell may be electrically programmed with data only once, and the programmed data is maintained even if power is no longer supplied to the OTP memory cell. For example, the OTP memory cell provides an anti-fuse element that includes a substrate and source and drain regions that are formed above the substrate and laterally spaced apart from each other to form a channel therebetween. In addition, the anti-fuse element includes a gate oxide layer formed on the channel and a gate formed on the gate oxide layer. The programming of the anti-fuse is performed by applying power to the gate and at least one of the source region and the drain region to break down the gate oxide layer, and thus minimizes the resistance between the gate and the channel. To determine an anti-fuse state, read voltage is applied to both ends of the gate oxide layer and the resulting current is read. Example embodiments are directed to an OTP memory in which the threshold voltage of the program transistor is set differently from the threshold voltage of the read transistor, thereby reducing or limiting the leakage current of the OTP memory cell, improving the signal setup speed, and reducing power consumption.

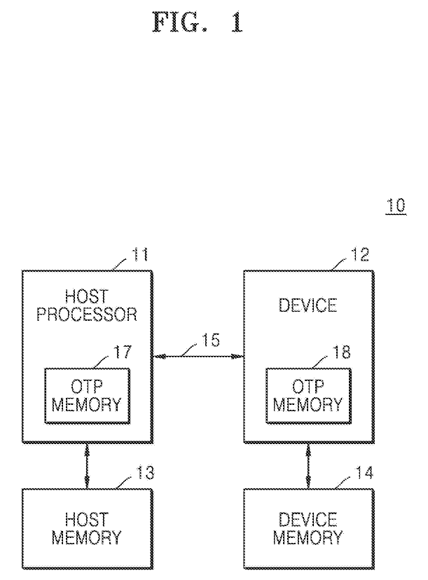

FIG. 1 illustrates a system according to some example embodiments. A system 10 of FIG. 1 may represent any computing system (or a component in a computing system) including a host processor 11 and a device 12 that communicate with each other. For example, the system 10 may be provided in a computing system, such as a desktop computer, a server, and a kiosk, or provided in a portable computing system, such as a laptop computer, a mobile phone, and a wearable device. Also, in some example embodiments, the system 10 may be provided in a system-on-chip (SoC) or a system-in-package (SiP) in which the host processor 11 and the device 12 are implemented on a single chip or package.

As shown in FIG. 1, the host processor 11 and the device 12 may communicate with each other via a link 15 and may send messages and/or data to and receive messages and/or data from each other through the link 15. For example, the host processor 11 and the device 12 may communicate with each other using coherent interconnect technologies, such as a compute express link (CXL) protocol, an XBus protocol, an NVLink protocol, an infinity fabric protocol, a cache coherent interconnect for accelerators (CCIX) protocol, and a coherent accelerator processor interface (CAPI).

In some example embodiments, the link 15 may support multiple protocols, and messages and/or data may be transmitted via the multiple protocols. For example, the link 15 may support CXL protocols that include a non-coherent protocol (e.g., CXL.io), a coherent protocol (e.g., CXL.cache), and a memory access protocol (or a memory protocol) (e.g., CXL.mem). The memory protocol may define transactions between a master and a subordinate. For example, the memory protocol may define transactions from the master to the subordinate and transactions from the subordinate to the master. The coherent protocol may define interactions between the host processor 11 and the device 12. For example, the interface of the coherent protocol may include three channels, including requests, responses, and data. The non-coherent protocol may provide a non-coherent load/store interface for input/output devices. In some example embodiments, the link 15 may support, as a non-limiting example, protocols, such as peripheral component interconnect (PCI), PCI express (PCIe), a universal serial bus (USB), and serial advanced technology attachment (SATA).

The device 12 may represent any device that provides a useful function to the host processor 11 and, in some example embodiments, may correspond to an accelerator in the CXL specification. For example, software running on the host processor 11 may offload at least some of the computing and/or input/output (I/O) operations to the device 12. In some example embodiments, the device 12 may include at least one of programmable components, such as a graphics processing unit (GPU) and a neural processing unit (NPU), fixed function-providing components, such as an intellectual property (IP) core, and reconfigurable components, such as a field programmable gate array (FPGA).

The device 12 may include a physical layer, a multi-protocol multiplexer, an interface circuit, and an accelerator circuit, and may communicate with a device memory 14. The accelerator circuit may perform functions that are provided by the device 12 to the host processor 11 and may communicate with the device memory 14 on the basis of a protocol that is independent of the link 15, for example, a device-specific protocol. The accelerator circuit may communicate with the host processor 11 via the interface circuit using multiple protocols. The interface circuit may determine one protocol among multiple protocols on the basis of messages and/or data for communication between the accelerator circuit and the host processor 11. The interface circuit may be connected to at least one protocol queue in a multi-protocol multiplexer and may exchange messages and/or data with the host processor 11 via the at least one protocol queue. The multi-protocol multiplexer may include multiple protocol queues respectively corresponding to the multiple protocols supported by the link 15, arbitrate between communications by different protocols, and provide the selected communication to the physical layer. The physical layer may be connected to a physical layer of the host processor 11 via a single interconnect, a bus, a trace, etc.

The host processor 11 may represent a main or primary processor of the system 10, for example, a central processing unit (CPU), and in some example embodiments, may correspond to a host processor (or a host) of the CXL specification. The host processor 11 may be connected to a host memory 13 and includes a physical layer, a multi-protocol multiplexer, an interface circuit, a coherence/cache circuit, a bus circuit, at least one core, and an I/O device. At least one core may execute instructions and be connected to the coherence/cache circuit. The coherence/cache circuit may include a cache hierarchy and communicate with at least one core and the interface circuit. For example, the coherence/cache circuit may enable communication via two or more protocols including a coherent protocol and a memory access protocol, and may include a direct memory access (DMA) circuit. The I/O device may be used to communicate with the bus circuit. For example, the bus circuit may include PCIe logic, and the I/O device may include a PCIe I/O device. The interface circuit may enable communication between components of the host processor 11, for example, between the coherence/cache circuit and bus circuit and the device 12. In some example embodiments, the interface circuit may enable communication of messages and/or data between the device 12 and components of the host processor 11 according to multiple protocols, for example, a non-coherent protocol, a coherent protocol, and a memory protocol. For example, the interface circuit may determine one protocol among multiple protocols on the basis of messages and/or data for communication between the device 12 and components of the host processor 11. The multi-protocol multiplexer may include at least one protocol queue. The interface circuit may be connected to at least one protocol queue and exchange messages and/or data with the device 12 via the at least one protocol queue.

In some example embodiments, the host processor 11 may execute hierarchical software including an operating system (OS) and/or applications running on the OS, and may access the host memory 13 and/or the device memory 14 on the basis of virtual memory.

The host processor 11 may program, in OTP memory 17, data required for operations of the host processor 11. The device 12 may program, in the OTP memory 18, data required for operations of the device 12. The data programmed in each of the OTP memories 17 and 18 may be used to control the operation of the host processor 11 or the device 12. Hereinafter, the OTP memories 17 and 18 are described in detail with reference to various example embodiments, and for sake of description, the OTP memories 17 and 18 are referred to as an OTP memory device 20, in the description below.

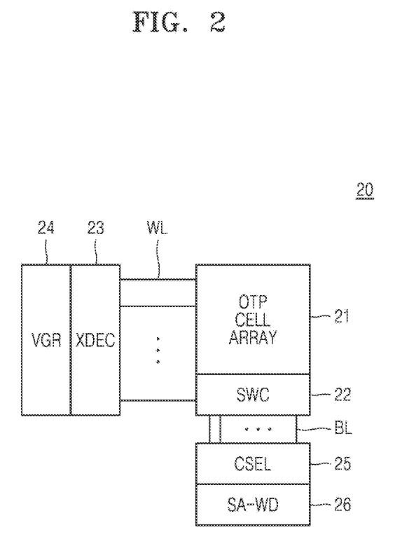

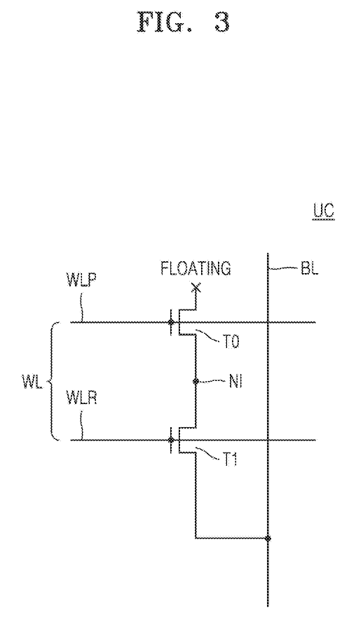

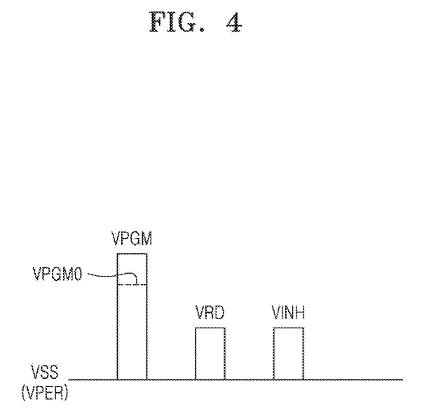

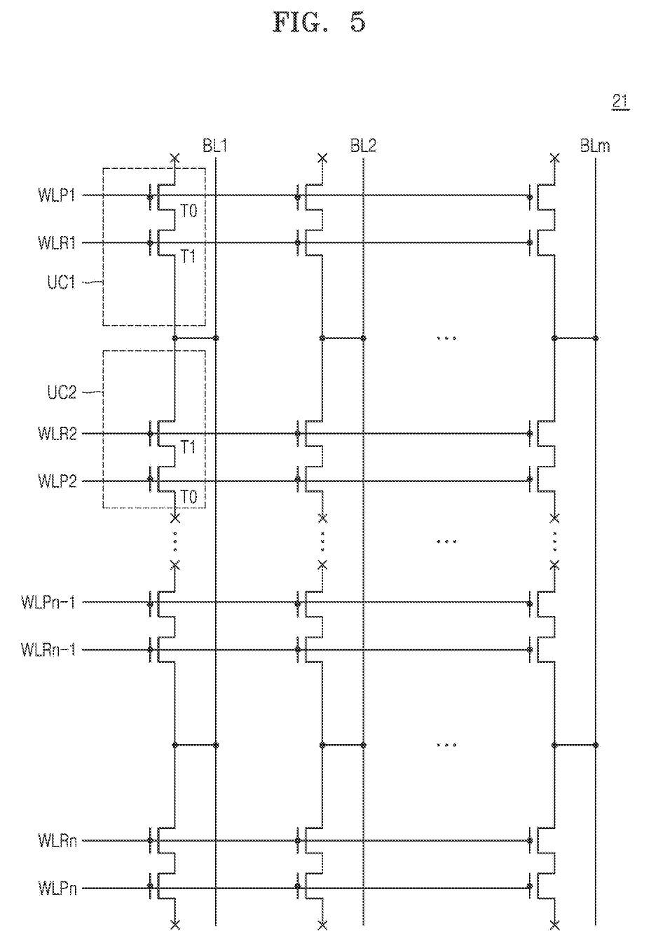

FIG. 2 is a block diagram showing an OTP memory device according to some example embodiments. FIG. 3 is a circuit diagram showing an example of an OTP memory cell in a memory cell array 21 of FIG. 2. FIG. 4 is a diagram showing the relationship between the operating voltages of the OTP memory cell of FIG. 3. FIG. 5 is a circuit diagram showing an example of the memory cell array 21 of FIG. 2. For sake of description, the term "memory cell array" and the term "OTP cell array" may be used interchangeably.

Referring to FIG. 2, the OTP memory device 20 may include a memory cell array 21, a switching circuit (SWC) 22, a row selection circuit (XDEC) 23, a voltage generation circuit (VGR) 24, a column selection circuit (CSEL) 25, and/or a write-read circuit (SA-WD) 26. The memory cell array 21 includes a plurality of OTP memory cells, which are respectively connected to a plurality of bit lines BL and a plurality of word lines WL. Each of the word lines WL may include a voltage word line WLP and a read word line WLR (FIG. 3). The SWC 22 may detect the program states of selected OTP memory cells among the plurality of OTP memory cells in a program mode. In FIG. 2, the memory cell array 21 and the SWC 22 are shown individually, but according to some example embodiments, the SWC 22 may be included in the memory cell array 21.

The XDEC 23 may include a row decoder for selecting a word line WL corresponding to a row address. The VGR 24 may generate operating voltages, such as a program voltage VPGM and a read voltage VRD, which are applied to the OTP memory cells (FIG. 4). The CSEL 25 may include a column gate circuit and a column decoder for selecting a bit line BL corresponding to a column address or a latch address. The column decoder may generate column selection signals on the basis of the column address or the latch address. The column gate circuit may include a plurality of switches that are selectively turned on in response to the column selection signals. One switch corresponding to the column address among the plurality of switches may be turned on to select a bit line.

The SA-WD 26 may include a read sense amplifier SA and a write driver WD. The SA-WD 26 is connected to the bit lines BL via the CSEL 25. The read sense amplifier SA performs a read operation that senses the data stored in the OTP memory cell and provides the read data. The write driver WD performs a write operation that stores the write data in the OTP memory cell. The write driver WD may be integrally formed with the read sense amplifier SA, as illustrated, or may be formed as a separate circuit distinct from the read sense amplifier SA.

As shown in FIG. 3, an OTP memory cell UC may include a program transistor T0 and a read transistor T1. The program transistor T0 represents a kind of anti-fuse and includes a structure capable of or otherwise, configured for changing a conduction state. The program transistor T0 is connected between the voltage word line WLP and an intermediate node NI. The read transistor T1 is connected between the intermediate node NI and the bit line BL and has a gate electrode connected to the read word line WLR. The program transistor T0 may have a drain electrode that is floating, a source electrode that is connected to the intermediate node NI, and a gate electrode that is connected to the corresponding voltage word line WLP.

In some example embodiments, the anti-fuse exhibits electrical characteristics opposite to those of a fuse element, and includes a resistive fuse element having a relatively high resistance value when not programmed and a relatively low resistance value when programmed. The anti-fuse is generally configured in a form in which a dielectric is inserted between conductors, and the anti-fuse is programmed by applying a high voltage via the conductors at both ends of the anti-fuse for a sufficient period of time to destroy the dielectric between the two conductors. As a result of the program, the conductors on both ends of the anti-fuse may be short-circuited and thus exhibit a relatively low resistance value. The anti-fuse type OTP memory represents a memory that is programmed by applying a high voltage to both ends of an MOS capacitor having a relatively thin gate oxide layer to electrically short-circuit a fuse, and may advantageously implement a low-power functional element due to its relatively smaller cell area and of being programmable in bytes due to the low current consumption during programming.

As shown in FIG. 4, in the OTP memory cell UC, the program voltage VPGM having a relatively higher voltage level may be applied to the voltage word line WLP in a program mode, and the read voltage VRD having a voltage level lower than the program voltage VPGM may be applied to the voltage word line WLP in a read mode. In the program mode and the read mode, a selection voltage having a voltage level capable of turning on the read transistor T1 according to the row address may be applied to the read word line WLR. For example, the program voltage VPGM may be set to 4 V (or approximately 4 V), which is higher than a power supply voltage (e.g., 2 V, or about 2 V) of the OTP memory device 20, and the read voltage VRD may be set to 1.2 V (or approximately 2 V).

In the program mode, the bit lines connected to programmed OTP memory cells may receive a program permission voltage VPER, and the bit lines connected to unprogrammed OTP memory cells may receive a program inhibition voltage VINH, which is greater than the program permission voltage VPER. For example, the program permission voltage VPER may be set to a ground voltage VSS of 0 V, and the program inhibition voltage VINH may be set to 2 V (or approximately 2 V).

In some example embodiments, the program inhibition voltage VINH may be set to the power supply voltage together with the read voltage VRD. The voltage levels of the operating voltages, such as the program voltage VPGM, the read voltage VRD, the program permission voltage VPER, and the program inhibition voltage VINH, may be set differently depending on the characteristics of the OTP memory cell and/or the configuration of the OTP memory device.

Referring to FIG. 5, the memory cell array 21 may include a plurality of OTP memory cells UC1 and UC2, which are arranged in an n*m matrix (where n and m are positive integers) and connected to a plurality of read word lines WLR1, ...., WLRn, a plurality of voltage word lines WLP1, ...., WLPn, and a plurality of bit lines BL1, ...., BLm. Each of the OTP memory cells UC1 and UC2 may include a program transistor T0 and a read transistor T1. A gate of the read transistor T1 may be connected to a corresponding read word line WLRx (where x is an integer from 1 to n), and a source region of the read transistor T1 may be connected to a corresponding bit line BLy (where y is an integer from 1 to m). A first end of the program transistor T0 may be connected to a corresponding voltage word line WLPx, and a second end of the program transistor T0 may be connected to a drain region of the read transistor T1. The gate of the program transistor T0 may be referred to as the first end described above and be connected to the corresponding voltage word line WLPx, the source region of the program transistor T0 may be referred to as the second end described above and be connected to the drain region of the read transistor T1, and the drain region of the program transistor T0 may be floating. FIG. 5 shows a configuration in which two OTP memory cells UC1 and UC2 form each pair, but the arrangement of unit cells may be made in various forms.

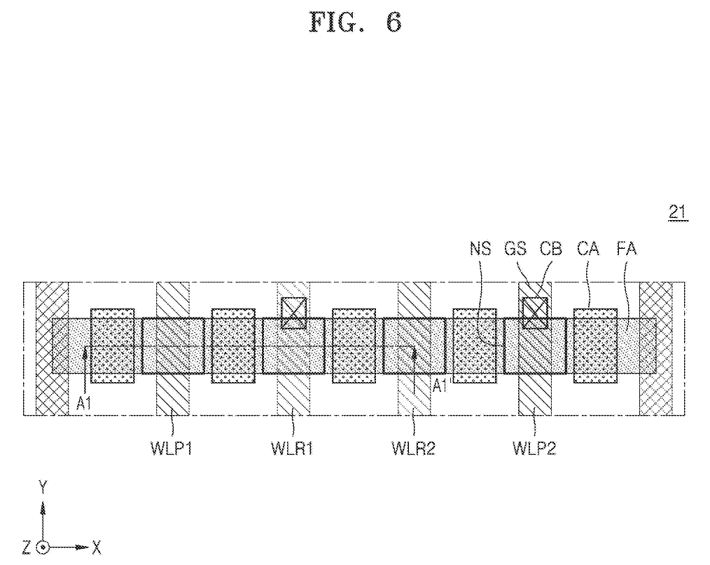

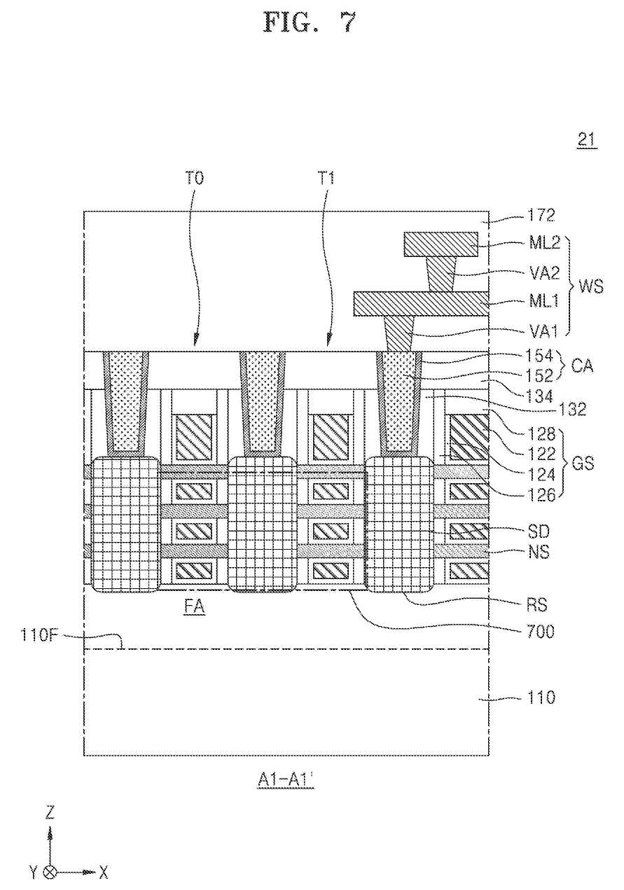

FIG. 6 is a schematic layout view showing an OTP memory cell array according to some example embodiments. FIG. 7 is a cross-sectional view of the OTP memory cell array taken along line A1-A1' of FIG. 6. For sake of explanation, the terms described as an upper surface, a lower surface, an upper portion, a lower portion, up/down, left/right, etc. are described with reference to the figures. Therefore, even a same surface may be referred to as the upper surface or the lower surface depending on the orientation in the figures.

Referring to FIG. 6 and FIG. 7, the OTP memory cell array 21 may include an OTP memory cell including a multi-bridge channel FET (MBCFET) element. However, example embodiments of the inventive concepts are not limited thereto, and the OTP memory cell array 21 may include a planar FET element, a gate-all-around type FET element, a FinFET element, or an FET element based on a two-dimensional material such as a MoS₂ semiconductor-gate electrode.

A fin-type active region FA may be arranged on a first surface 110F of a substrate 110, and an element isolation layer may cover the lower side of the sidewall of the fin-type active region FA. The element isolation layer may fill the inside of an element isolation trench extending from the first surface 110F of the substrate 110 into the substrate 110 and may have, for example, a double layer structure of an interface layer and a buried insulating layer.

A plurality of semiconductor patterns NS may be spaced apart from each other in a vertical direction Z above the fin-type active region FA. The plurality of semiconductor patterns NS may each include group IV semiconductors, such as Si and Ge, group IV-IV compound semiconductors, such as SiGe and SiC, or group III-V compound semiconductors, such as GaAs, InAs, and InP. The plurality of semiconductor patterns NS may each have a relatively large width in a second horizontal direction Y and a relatively small thickness in the vertical direction Z, and may have, for example, a shape of a nanosheet.

A plurality of gate structures GS may extend in the second horizontal direction Y to surround the plurality of semiconductor patterns NS and may be spaced apart from each other in a first horizontal direction X by first gate intervals. Each of the plurality of gate structures GS may include a gate electrode 122, a gate insulating layer 124, a gate spacer 126, and a gate capping layer 128. For example, the gate electrodes 122 may extend in the second horizontal direction Y to surround the plurality of semiconductor patterns NS above the fin-type active region FA, and the gate insulating layers 124 may be arranged between the gate electrode 122 and the fin-type active region FA and between the gate electrode 122 and each of the semiconductor patterns NS. The gate spacers 126 may be arranged on both sidewalls of the gate electrode 122, and the gate capping layer 128 may extend in the second horizontal direction Y on the gate electrode 122 and the gate insulating layer 124.

In some example embodiments, the gate electrode 122 may include doped polysilicon, metal, conductive metal nitride, conductive metal carbide, conductive metal silicide, or a combination thereof. For example, the gate electrode 122 may include, but is not limited to, Al, Cu, Ti, Ta, W, Mo, TaN, NiSi, CoSi, TiN, WN, TiAl, TiAlN, TaCN, TaC, TaSiN, or a combination thereof. In some example embodiments, the gate electrode 122 may include a work function metal-containing layer and a gap-fill metal layer . The work function metal-containing layer may include at least one metal selected from a group consisting of Ti, W, Ru, Nb, Mo, Hf, Ni, Co, Pt, Yb, Tb, Dy, Er, and Pd. The gap-fill metal layer may include a W layer or an Al layer. In some example embodiments, the gate electrode 122 may include a stack structure of TiAlC/TiN/W, a stack structure of TiN/TaN/TiAlC/TiN/W, or a stack structure of TiN/TaN/TiN/TiAlC/TiN/W, but example embodiments are not limited thereto.

In some example embodiments, the gate insulating layer 124 may include a silicon oxide layer, a silicon oxynitride layer, a high-k dielectric layer having a higher dielectric constant than the silicon oxide layer, or a combination thereof. The high-k dielectric layer may include metal oxide or metal oxynitride. For example, the high-k dielectric layer that may be used as the gate insulating layer 124 may include, but is not limited to, HfO₂, HfSiO, HfSiON, HfTaO, HfTiO, HfZrO, ZrO₂, Al2O₃, or a combination thereof.

In some example embodiments, the gate spacer 126 may include silicon oxide (SiOₓ), silicon nitride (SiNₓ), silicon oxynitride (SiOₓN_{y}), silicon carbonitride (SiCₓN_{y}), silicon oxycarbonitride (SiOₓC_{y}N_{z}), or a combination thereof. In some example embodiments, the gate capping layer 128 may include silicon nitride or silicon oxynitride.

Recesses RS may be formed on both sides of the gate structure GS and extend into the fin-type active region FA, and source/drain regions SD may be formed in the recesses RS. The source/drain region SD may be formed in the recess RS and connected to both ends of the plurality of semiconductor patterns NS. The source/drain region may have the upper surface that is at a higher level than the upper surface of an uppermost semiconductor pattern NS. The source/drain region SD may include a plurality of inclined sidewalls and have a vertical cross-sectional shape, for example, a hexagon, pentagon, rhombus, or a polygon having rounded corners.

In some example embodiments, the source/drain region SD may include, but is not limited to, a doped SiGe layer, a doped Ge layer, a doped SiC layer, or a doped InGaAs layer. The recesses RS may be formed by partially removing the semiconductor patterns NS on both sides of the gate structures GS, and the source/drain regions SD may be formed by growing, using an epitaxy process, semiconductor layers that fill the recesses RS. In some example embodiments, the source/drain region SD may include a plurality of semiconductor layers having different compositions. For example, the source/drain region SD may include a lower semiconductor layer, an upper semiconductor layer, and a capping semiconductor layer, which sequentially fill the inside of the recess RS. For example, the lower semiconductor layer, the upper semiconductor layer, and the capping semiconductor layer may each contain SiC and have different contents of Si and C.

An inter-gate insulating layer 132 may be formed to cover the source/drain region SD between the gate structures GS. An upper insulating layer 134 may be disposed on the inter-gate insulating layer 132 and the gate structure GS. The inter-gate insulating layer 132 and the upper insulating layer 134 may include silicon oxide, silicon carbon oxide, or silicon oxynitride.

A first contact CA may be disposed on the source/drain region SD. For example, the first contact CA may include a contact plug 152 and a conductive barrier layer 154, which are arranged inside a first contact hole that passes through the inter-gate insulating layer 132 and the upper insulating layer 134. The contact plug 152 may include at least one of tungsten (W), cobalt (Co), molybdenum (Mo), nickel (Ni), ruthenium (Ru), copper (Cu), aluminum (Al), a silicide thereof, and an alloy thereof. The conductive barrier layer 154 may include at least one of ruthenium (Ru), titanium (Ti), titanium nitride (TiN), tantalum (Ta), tantalum nitride (TaN), tungsten (W), titanium silicon nitride (TiSiN), titanium silicide (TiSi), and tungsten silicide (WSi). A metal silicide layer may be further provided between the first contact CA and the source/drain region SD.

A second contact CB may be disposed on the gate structure GS. The second contact CB may include a contact plug and a conductive barrier layer surrounding the sidewall and bottom surface of the contact plug. The second contact CB may be located inside a second contact hole that passes through the upper insulating layer 134 and the gate capping layer 128 to expose the upper surface of the gate electrode 122.

A wiring structure WS may be disposed on the upper insulating layer 134. The wiring structure WS may include wiring layers ML1 and ML2 and vias VA1 and VA2, and an interlayer insulating layer 172 may cover the wiring structure WS on the upper insulating layer 134. For example, the interlayer insulating layer 172 may include a plurality of material layers, and each of the material layers may cover the upper surface and the bottom surface of each of the wiring layers ML1 and ML2 and surround the sidewalls of the vias VA1 and VA2. In some example embodiments, the interlayer insulating layer 172 may include an oxide layer, a nitride layer, or a combination thereof.

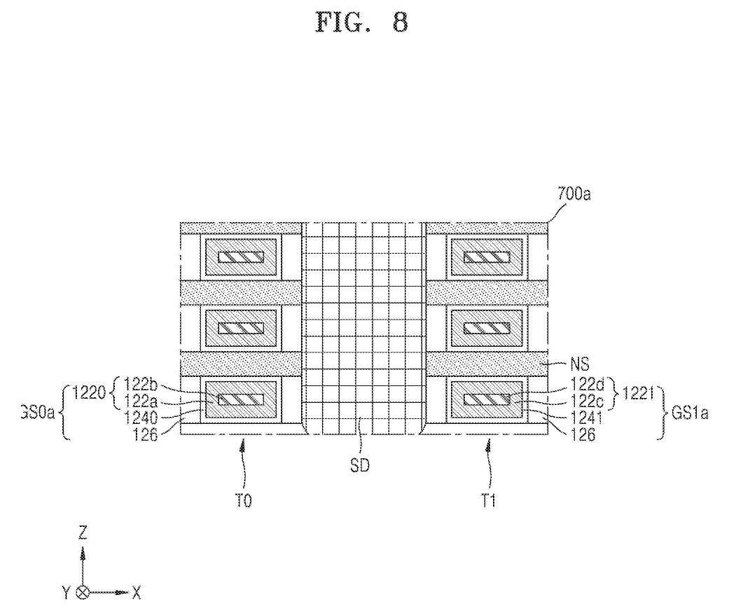

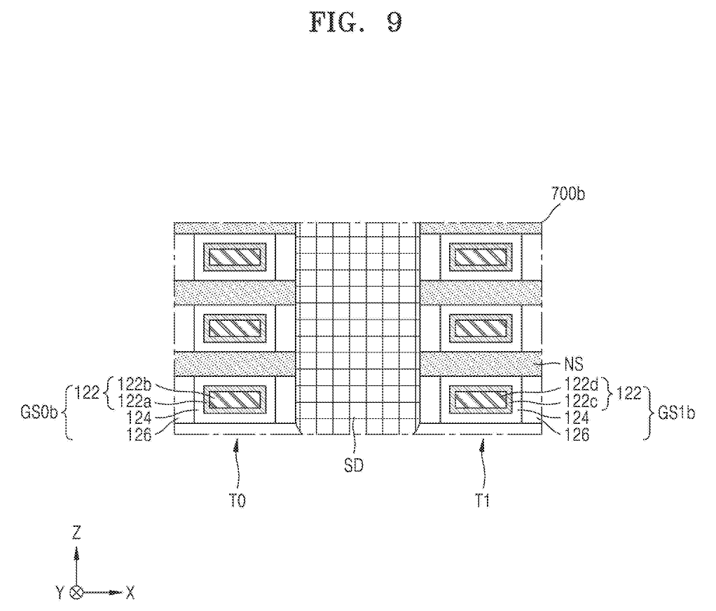

FIGS. 8 and 9 are diagrams illustrating gate structures of OTP memory cells according to some example embodiments. FIGS. 8 and 9 show enlarged views of region 700 in FIG. 7. Hereinafter, suffixes (e.g., a in 700a and b in 700b) attached to the same reference numerals in different drawings are intended to distinguish a plurality of components that have similar or identical functions.

Referring to FIGS. 3, 7, and FIG. 8, in the OTP memory cell UC, a gate structure GS0a of the program transistor T0 and a gate structure GS1a of the read transistor T1 are formed such that, except a gate spacer 126, gate insulating layers 1240 and 1241 and gate electrodes 1220 and 1221 have different structures. The gate structure GS0a of the program transistor T0 and the gate structure GS1a of the read transistor T1 may include gate capping layers 128 having the same structure.

A gate electrode 1220 of the program transistor T0 may include a first metal layer 122a and a second metal layer 122b, and a gate electrode 1221 of the read transistor T1 may include a first metal layer 122c and a second metal layer 122d. The thickness of the first metal layer 122a of the gate electrode 1220 of the program transistor T0 may be different from the thickness of the first metal layer 122c of the gate electrode 1221 of the read transistor T1, and the thickness of the first metal layer 122a may be greater than the thickness of the first metal layer 122c.

A gate insulating layer 1240 of the program transistor T0 may have a structure in which breakdown may occur with relative ease. The first metal layer 122a of the gate electrode 1220 of the program transistor T0 and the first metal layer 122c of the gate electrode 1221 of the read transistor T1 may be formed as a TiN layer that has the function of adjusting a work function of a metal electrode. When the first metal layers 122a and 122c include a TiN layer containing p-type impurity ions, the threshold voltage may decrease as the thicknesses of the first metal layers 122a and 122c decrease. Accordingly, a threshold voltage (Vth1) of the read transistor T1 may be lower than a threshold voltage (Vth0) of the program transistor T0. When the threshold voltage (Vth1) of the read transistor T1 is lowered, the amount of current increases during a read operation of the OTP memory cell UC. Accordingly, a signal setup speed of the bit line may be improved.

The thickness of the gate insulating layer 1240 of the program transistor T0 may be relatively less than the thickness of a gate insulating layer 1241 of the read transistor T1. The breakdown may easily occur in the gate insulating layer 1240 of the program transistor T0. That is, the program transistor T0 may have a structure in which breakdown easily occurs even when a low programming voltage is applied.

Also, since a program transistor in an existing OTP memory requires a high programming voltage VPGM of 4 V or more (FIG. 4), a charge-pump circuit and/or a level-shifter circuit may be used to apply the high voltage. A relatively higher amount of power consumption may occur due to the operation of the charge pump and level-shifter, which generates a high voltage of 4V or more. On the other hand, since a programming voltage VPGM0 (FIG. 4) of the program transistor T0 may be lowered in some example embodiments, the power consumption of the OTP memory device 20 may be reduced and the programming efficiency may be improved.

Referring to FIG. 9, in the OTP memory cell UC, a gate structure GS0b of the program transistor T0 and a gate structure GS1b of the read transistor T1 may have a structure that is same as or similar in some respects to the gate structure GS described with reference to FIG. 7 and may include a gate insulating layer 124, a gate electrode 122, and a gate spacer 126. A gate electrode 122 of the program transistor T0 may include a first metal layer 122a and a second metal layer 122b, and a gate electrode 122 of the read transistor T1 may include a first metal layer 122c and a second metal layer 122d.

In order to make a threshold voltage (Vth0) of the program transistor T0 and a threshold voltage (Vth1) of the read transistor T1 different from each other, the concentration of lanthanum (La) or aluminum (Al) contained in the gate electrode 122 of the program transistor T0 and the gate electrode 122 of the read transistor T1 may be adjusted. Lanthanum (La) forms a dipole with a material, for example SiO₂ or SiON, at the interface of the gate insulating layer 124 through diffusion, and may thus change the threshold voltage (Vth0) of the program transistor T0 and the threshold voltage (Vth1) of the read transistor T1. As lanthanum (La) is supplied to the interface of the gate insulating layer 124, the threshold voltage (Vth0) of the program transistor T0 and the threshold voltage (Vth1) of the read transistor T1 may change. The work function of the metal electrode may be adjusted by the diffusion of aluminum (Al), and the work function may also be adjusted by the movement of electrons between first metal layer 122a and 122c and the second metal layer 122b and 122d. As the work function is adjusted by the diffusion of aluminum (Al) and the movement of electrons, the threshold voltage (Vth0) of the program transistor T0 and the threshold voltage (Vth1) of the read transistor T1 may change.

The concentration of lanthanum (La) contained in the first metal layer 122a and/or the second metal layer 122b of the gate electrode 122 of the program transistor T0 may be less than the concentration of lanthanum (La) contained in the first metal layer 122c and/or the second metal layer 122d of the gate electrode 122 of the read transistor T1. The amount of lanthanum (La) supplied to the interface of the gate insulating layer 124 of the read transistor T1 may be relatively greater than the amount of lanthanum (La) supplied to the interface of the gate insulating layer 124 of the program transistor T0. Accordingly, the threshold voltage (Vth1) of the read transistor T1 is lower than the threshold voltage (Vth0) of the program transistor T0. The threshold voltage (Vth0) of the program transistor T0 may have a relatively higher value. When the threshold voltage (Vth1) of the read transistor T1 is lowered, the amount of current increases during a read operation of the OTP memory cell UC. Accordingly, a signal setup speed of the bit line may be improved. When the threshold voltage (Vth0) of the program transistor T0 increases, the leakage current of the program transistor T0 may be reduced or suppressed.

The concentration of aluminum (Al) contained in the first metal layer 122a and/or the second metal layer 122b of the gate electrode 122 of the program transistor T0 may be greater than the concentration of aluminum (Al) contained in the first metal layer 122c and/or the second metal layer 122d of the gate electrode 122 of the read transistor T1. The amount of aluminum (Al) supplied to the interface of the gate insulating layer 124 of the program transistor T0 may be greater than the amount of aluminum (Al) supplied to the interface of the gate insulating layer 124 of the read transistor T1. Accordingly, the threshold voltage (Vth0) of the program transistor T0 is higher than the threshold voltage (Vth1) of the read transistor T1. The threshold voltage (Vth1) of the read transistor T1 may have a low value. When the threshold voltage (Vth1) of the read transistor T1 is lowered, the amount of current increases during a read operation of the OTP memory cell UC. Accordingly, a signal setup speed of the bit line may be improved. When the threshold voltage (Vth0) of the program transistor T0 increases, the leakage current of the program transistor T0 may be reduced or suppressed.

In some example embodiments, the thickness of the gate insulating layer 124 of the program transistor T0 may be relatively less than the thickness of the gate insulating layer 124 of the read transistor T1, as shown in the gate insulating layers 1240 of FIG. 8. Accordingly, since breakdown occurs with relative ease in the gate insulating layer 124 of the program transistor T0, the program transistor T0 may be programmed by applying a relatively lower programming voltage.

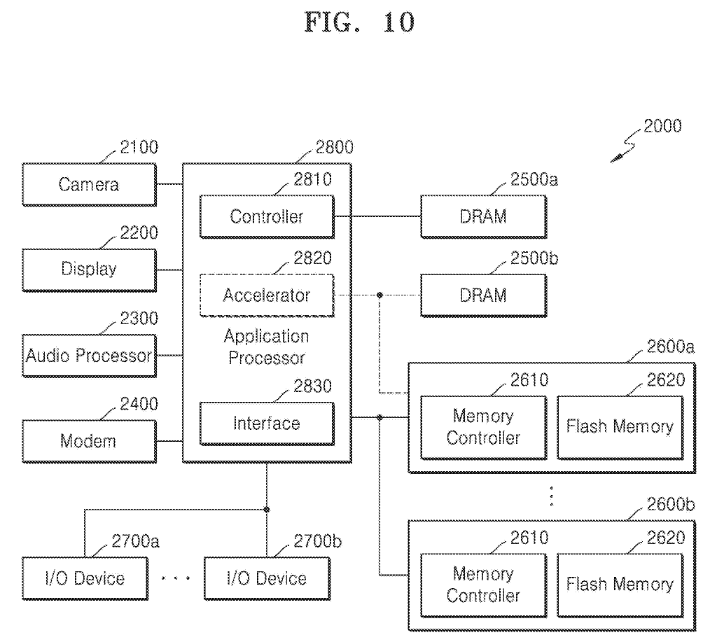

FIG. 10 is a block diagram of a system 2000 and illustrates an electronic product including an OTP memory device according to some example embodiments.

As shown in FIG. 10, the system 2000 may include a camera 2100, a display 2200, an audio processor 2300, a modem 2400, DRAMs 2500a and 2500b, flash memories 2600a and 2600b, I/O devices 2700a and 2700b, and an application processor 2800 (hereinafter referred to as "AP"). The system 2000 may be provided as a laptop computer, a mobile phone, a smart phone, a tablet personal computer, a wearable device, a healthcare device, or an IoT device. In addition, the system 2000 may be provided as a server or a personal computer.

The camera 2100 may capture still images or moving images under control by a user, and store the captured image/video data or transmit the data to the display 2200. The audio processor 2300 may process audio data contained in the contents of the flash memories 2600a and 2600b or a network. The modem 2400 may modulate and transmit signals for the transmission and reception of wired and wireless data, and may perform demodulation so that the signals are restored to the original signals at a receiver. The I/O devices 2700a and 2700b may include devices that provide digital input and/or output functions, such as a universal serial bus (USB) or storage, a digital camera, a secure digital (SD) card, a digital versatile disc (DVD), a network adapter, and a touch screen.

The AP 2800 may control overall operations of the system 2000. The AP 2800 may include a control block 2810, an accelerator block or an accelerator chip 2820, and an interface block 2830. The AP 2800 may control the display 2200 such that the contents (or at least portions thereof) stored in the flash memories 2600a and 2600b are displayed on the display 2200. When a user input is received via the I/O devices 2700a and 2700b, the AP 2800 may perform a control operation in response to the user input. The AP 2800 may include an accelerator block, which may be a dedicated or specialized circuit for computing artificial intelligence (AI) data, or may have the accelerator chip 2820 separate from the AP 2800. The accelerator block or the accelerator chip 2820 may be further equipped with the DRAM 2500b. An accelerator represents a function block specialized in performing a particular function of the AP 2800, and the accelerator may include a GPU, which is a function block specialized in processing graphic data, an NPU, which is a block specialized in performing AI computation and inference, and a data processing unit (DPU), which is a block specialized in data transmission. In some example embodiments, the images captured by the user through the camera 2100 are signal-processed and stored in the DRAM 2500b, and the accelerator block or the accelerator chip 2820 may perform AI data calculation to identify the data by using the data stored in the DRAM 2500b and the functions used in the reference.

The system 2000 may include the plurality of DRAMs 2500a and 2500b. The AP 2800 may control the DRAMs 2500a and 2500b by setting a mode register (MRS) and commands conforming to Joint Electron Device Engineering Council (JEDEC) standards, or may perform communication by establishing DRAM interface protocols to utilize vendor-specific functions, such as low voltage/high speed/reliability, and cyclic redundancy check (CRC)/error correction code (ECC) functions. For example, the AP 2800 may communicate with the DRAM 2500a over an interface conforming to JEDEC standards, such as low power double data rate 4th generation (LPDDR4) and low power double data rate 5th generation (LPDDR5), and the accelerator block or the accelerator chip 2820 may perform communication by establishing a new DRAM interface protocol to control the DRAM 2500b for an accelerator that has a higher bandwidth than the DRAM 2500a.

FIG. 10 illustrates DRAMs 2500a and 2500b, but example embodiments are not limited thereto. Any other types of memory, such as phase-change random-access memory (PRAM), static random-access memory (SRAM), magnetic random-access memory (MRAM), resistive random-access memory (RRAM), ferroelectric random-access memory (FRAM), and hybrid RAM memory, may be used as long as the memory satisfies the bandwidth, response speed, and voltage requirements of the AP 2800 or the accelerator chip 2820. The DRAMs 2500a and 2500b have relatively less latency and bandwidth than the I/O devices 2700a and 2700b or the flash memories 2600a and 2600b. The DRAMs 2500a and 2500b may be initialized at the time of power-on of the system 2000, and may be used as temporary storages for an operating system and application data when the operating system and application data are loaded or may be used as execution spaces for various pieces of software code.

Arithmetic operations, such as addition, subtraction, multiplication, and division, vector operations, address operations, or fast Fourier transform (FFT) operations may be performed in the DRAMs 2500a and 2500b. In addition, a function for execution used for inference may be performed inside the DRAMs 2500a and 2500b. Here, the inference may be performed by a deep learning algorithm using an artificial neural network. The deep learning algorithm may include a training phase, in which a model is trained by using various pieces of data, and an inference phase, in which data is identified by the trained model.

The system 2000 may include a plurality of storage or the plurality of flash memories 2600a and 2600b having greater capacities than the DRAMs 2500a and 2500b. The accelerator block or the accelerator chip 2820 may utilize the flash memories 2600a and 2600b to perform the training phase and the AI data calculation. In some example embodiments, the flash memories 2600a and 2600b each include a memory controller 2610 and a flash memory device 2620, and the training stage and the inference AI data calculation performed by the AP 2800 and/or the accelerator chip 2820 may be performed more efficiently using an arithmetic unit provided in the memory controller 2610. The flash memories 2600a and 2600b may store images captured by the camera 2100 or data transmitted via a data network. For example, augmented reality (AR)/virtual reality (VR), high definition (HD), or ultra-high definition (UHD) contents may be stored.

The components of the system 2000 may include the OTP memory devices described with reference to FIGS. 1 to 9. The OTP memory device includes OTP memory cells having asymmetric metal gates. The OTP memory cell may include a program transistor, which has a first threshold voltage and a first breakdown voltage, and a read transistor, which is connected to the program transistor and has a second threshold voltage and a second breakdown voltage. The program transistor and the read transistor may each include a fin-type active region extending in a first direction on a substrate, a plurality of semiconductor patterns spaced apart from the upper surface of the fin-type active region and having a channel region, and gate electrodes extending in a second direction intersecting the first direction above the fin-type active region and arranged respectively between the plurality of semiconductor patterns. The first gate electrode of the program transistor may include a first gate insulating layer surrounding the first gate electrode, and the second gate electrode of the read transistor may include a second gate insulating layer surrounding the second gate electrode. The thickness of the first gate electrode may be greater than the thickness of the second gate electrode. A first concentration of lanthanum contained in the first gate electrode may be less than a second concentration of lanthanum contained in the second gate electrode. A first concentration of aluminum (Al) contained in the first gate electrode may be greater than a second concentration of aluminum (Al) contained in the second gate electrode.

As described herein, any devices, systems, modules, portions, units, controllers, circuits, and/or portions thereof according to any of the example embodiments, and/or any portions thereof (including, without limitation, host processor 11, the device 12, the camera 2100, the display 2200, the audio processor 2300, the modem 2400, the I/O devices 2700a and 2700b, and the application processor 2800, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A one-time-programmable (OTP) memory device comprising:
a plurality of OTP memory cells, wherein each of the plurality of OTP memory cells comprises,
a program transistor having a first threshold voltage and a first breakdown voltage; and
a read transistor connected to the program transistor and having a second threshold voltage and a second breakdown voltage, and
wherein each of the program transistor and the read transistor comprises,
a fin-type active region extending in a first direction on a substrate;
a plurality of semiconductor patterns defining a channel region and spaced apart from an upper surface of the fin-type active region; and
gate electrodes extending in a second direction intersecting the first direction above the fin-type active region and arranged respectively between the plurality of semiconductor patterns, and
wherein
a first gate electrode of the program transistor comprises a first gate insulating layer surrounding the first gate electrode,
a second gate electrode of the read transistor comprises a second gate insulating layer surrounding the second gate electrode, and
a thickness of the first gate electrode is greater than a thickness of the second gate electrode.

2. The OTP memory device of claim 1, wherein the first threshold voltage is greater than the second threshold voltage.

3. The OTP memory device of claim 1, wherein the first gate insulating layer surrounding the first gate electrode of the program transistor is thinner than the second gate insulating layer surrounding the second gate electrode of the read transistor.

4. The OTP memory device of claim 3, wherein the first breakdown voltage is less than the second breakdown voltage.

5. The OTP memory device of claim 1, wherein the first gate electrode and the second gate electrode each comprise lanthanum (La), and a first concentration of the lanthanum (La) in the first gate electrode is less than a second concentration of the lanthanum (La) in the second gate electrode.

6. The OTP memory device of claim 5, wherein the first threshold voltage is greater than the second threshold voltage.

7. The OTP memory device of claim 1, wherein the first gate electrode and the second gate electrode each comprise aluminum (Al), and a first concentration of the aluminum (Al) in the first gate electrode is greater than a second concentration of the aluminum (Al) in the second gate electrode.

8. The OTP memory device of claim 7, wherein the first threshold voltage is greater than the second threshold voltage.

9. A one-time-programmable (OTP) memory device comprising:
a plurality of OTP memory cells, wherein each of the plurality of OTP memory cells comprises,
a program transistor having a first threshold voltage and a first breakdown voltage; and
a read transistor connected to the program transistor and having a second threshold voltage and a second breakdown voltage, and
wherein each of the program transistor and the read transistor comprises,
a fin-type active region extending in a first direction on a substrate;
a plurality of semiconductor patterns defining a channel region and spaced apart from an upper surface of the fin-type active region; and
gate electrodes extending in a second direction intersecting the first direction above the fin-type active region and arranged respectively between the plurality of semiconductor patterns, and
wherein
a first gate electrode of the program transistor comprises a first gate insulating layer surrounding the first gate electrode,
a second gate electrode of the read transistor comprises a second gate insulating layer surrounding the second gate electrode,
the first gate electrode and the second gate electrode each comprise lanthanum (La), and
a first concentration of the lanthanum (La) in the first gate electrode is less than a second concentration of the lanthanum (La) in the second gate electrode.

10. The OTP memory device of claim 9, wherein the first threshold voltage is greater than the second threshold voltage.

11. The OTP memory device of claim 9, wherein the first gate electrode and the second gate electrode have a same thickness.

12. The OTP memory device of claim 9, wherein the first gate insulating layer and the second gate insulating layer have a same thickness.

13. The OTP memory device of claim 9, wherein the first gate insulating layer is thinner than the second gate insulating layer.

14. The OTP memory device of claim 13, wherein the first breakdown voltage is less than the second breakdown voltage.

15. A one-time-programmable (OTP) memory device comprising:
a plurality of OTP memory cells, wherein each of the plurality of OTP memory cells comprises,
a program transistor having a first threshold voltage and a first breakdown voltage; and
a read transistor connected to the program transistor and having a second threshold voltage and a second breakdown voltage, and
wherein each of the program transistor and the read transistor comprises,
a fin-type active region extending in a first direction on a substrate;
a plurality of semiconductor patterns defining a channel region and spaced apart from an upper surface of the fin-type active region; and
gate electrodes extending in a second direction intersecting the first direction above the fin-type active region and arranged respectively between the plurality of semiconductor patterns, and
wherein
a first gate electrode of the program transistor comprises a first gate insulating layer surrounding the first gate electrode,
a second gate electrode of the read transistor comprises a second gate insulating layer surrounding the second gate electrode,
the first gate electrode and the second gate electrode each comprise aluminum (Al), and
a first concentration of the aluminum (Al) in the first gate electrode is greater than a second concentration of the aluminum (Al) in the second gate electrode.

16. The OTP memory device of claim 15, wherein the first threshold voltage is greater than the second threshold voltage.

17. The OTP memory device of claim 15, wherein the first gate electrode and the second gate electrode have a same thickness.

18. The OTP memory device of claim 15, wherein the first gate insulating layer and the second gate insulating layer have a same thickness.

19. The OTP memory device of claim 15, wherein the first gate insulating layer is thinner than the second gate insulating layer.

20. The OTP memory device of claim 15, wherein the first breakdown voltage is less than the second breakdown voltage.
